(19) United States
(12) Patent Application Publication
(10) Pub. No.: US 2026/0193769 A1
(43) Pub. Date: Jul. 9, 2026

(54) METHOD OF PRODUCING HARD MASK

(71) Applicant: ULVAC, INC., Kanagawa (JP)

(72) Inventors: Shinji KOHARI, Kanagawa (JP); Motohide NISHIMURA, Kanagawa (JP); Keita ARAI, Kanagawa (JP)

(73) Assignee: ULVAC, INC., Kanagawa (JP)

(21) Appl. No.: 19/132,452

(22) PCT Filed: Feb. 16, 2024
(86) PCT No.: PCT/JP2024/005418

§ 371 Date: May 23, 2025

(30) Foreign Application Priority Data
May 30, 2023 (JP) 2023-088871

(51) Int. Cl. C23C 14/18; C23C 14/34

(52) U.S. Cl. CPC C23C 14/18; C23C 14/3414

(57) ABSTRACT

A target is made of tungsten, a rare gas and nitrogen gas are introduced into a processing chamber of a vacuum atmosphere, and a tungsten nitride film is deposited on a surface of a substrate to be treated by a reactive sputtering manner, and a second step in which a target is made of tungsten, and a tungsten film is deposited on a surface of the tungsten nitride film in a processing chamber of the vacuum atmosphere are included. A flow rate ratio of the rare gas to the nitrogen gas and a pressure in the processing chamber are set to 1.5 or less and 1 Pa or more, respectively, in the first step, and a stress is adjusted depending on a film thickness of the tungsten film by controlling at least one of a total pressure in the processing chamber and a bias electric power supplied to the substrate to be treated at the time of deposition in the second step.

### TECHNICAL FIELD

The invention relates to a method of producing a hard mask.

### BACKGROUND ART

For example, in a production process of a semiconductor device, there is a step in which dry etching is performed on a predetermined thin film (for example, SiO₂ film) deposited on a substrate to be treated. In this step, a treatment range of the dry etching is limited by providing a (metallic) hard mask, for example, with a surface of the substrate to be treated. As a hard mask of this type, it has been known in Patent Document No. 1, for example, that the one has a tungsten nitride film as an underlayer and a tungsten film laminated on the tungsten nitride film. In the step, as a first step, a target is made of tungsten, a rare gas and nitrogen gas are introduced into a processing chamber of a vacuum atmosphere, and a tungsten nitride film is deposited on a surface of the substrate to be treated by reactive sputtering. In addition, as a second step, the target is made of tungsten, and a tungsten film is deposited on the tungsten nitride film in the processing chamber by sputtering. After that, a desired opening part is patterned and formed, for example, by lithography technology.

Here, the following case has been known. The tungsten film deposited by sputtering has a high density compared to a carbon film or the like and is excellent in dry etching resistance. On the other hand, the tungsten film is a crystalline film of which a grain size is large (more than 100 nm), and at the time of patterning and formation, the tungsten film causes deterioration of a processed shape. Therefore, it is desirable for the tungsten film to be a microcrystalline film of which the grain size is as small as possible, but it may also be necessary to maintain a film stress in a predetermined range. For example, in a case where, for example, being able to focus sufficiently is required in the lithography step, it is desirable that a film stress is, for example, within ±300 MPa (preferably, ±100 MPa, for example).

### REFERENCE

Patent Document No. 1: JP2022-27215 A

### SUMMARY OF INVENTION

### Technical Problems

In light of the foregoing problem, the invention provides a method of manufacturing the hard mask which, while making the tungsten film a microcrystalline film, is capable of adjusting the film stress depending on a film thickness.

### Solution to Problem

In order to solve the foregoing problem, a method of producing a hard mask, including: a first step in which a target is made of tungsten, a rare gas and nitrogen gas are introduced into a processing chamber of a vacuum atmosphere, and a tungsten nitride film is deposited on a surface of a substrate to be treated by a reactive sputtering manner; and a second step in which a target is made of tungsten, and a tungsten film is deposited on a surface of the tungsten nitride film in a processing chamber of the vacuum atmosphere, wherein a flow rate ratio of the rare gas to the nitrogen gas and a pressure in the processing chamber are set to 1.5 or less and 1 Pa or more, respectively, in the first step, and a stress is adjusted depending on a film thickness of the tungsten film by controlling at least one of a total pressure in the processing chamber and a bias electric power supplied to the substrate to be treated at the time of deposition in the second step.

Here, after diligent research by the inventors, the following knowledge has been reached. That is, when the tungsten nitride film is deposited on the surface of the substrate to be treated by the reactive sputtering manner in the first step, as the flow rate ratio of the nitrogen gas to the rare gas and the pressure in the processing chamber are increased, although a grain size of the tungsten film deposited in the second step becomes small, the stress of the tungsten film (absolute value) becomes large. Based on such knowledge, the invention adopts the configuration in which the flow rate ratio of the rare gas to the nitrogen gas and the pressure in the processing chamber are set to 1.5 or less and 1 Pa or more, respectively, and the tungsten nitride film is deposited in the first step, and the tungsten film is deposited on the tungsten nitride film in the subsequent second step. Thus, a microcrystalline tungsten film of which a grain size is small (for example, 60 nm or less) can be deposited over an entire in-plane direction of the substrate to be treated. In addition, when controlling at least one of the total pressure in the processing chamber and the bias electric power supplied to the substrate to be treated at the time of deposition, in the second step, the stress of the tungsten film can be adjusted to a predetermined range (for example, within ±300 MPa, more preferably, within ±100 MPa).

It should be noted that in the invention, in a case where the bias electric power to the substrate to be treated is supplied by an AC power source connected through a matching box, it is preferable that control of the bias electric power includes the time until an impedance matching by the matching box. According to this, even when the pressure in the processing chamber in the second step is relatively high, the stress of the tungsten film can be effectively adjusted.

### BRIEF DESCRIPTION OF THE DRAWINGS

FIG. 1 is a schematic cross-section of a hard mask of an embodiment of the invention.

FIG. 2 is a schematic cross-section of a sputtering apparatus capable of carrying out a method of producing a hard mask of an embodiment.

FIGS. 3A to 3C are AFM images showing results of Invention Experiments, respectively, to confirm an effect of the invention. FIGS. 3D to 3F and FIGS. 3G to 3I are AFM images showing results of Comparative Experiments Nos. 1, 2, respectively.

FIG. 4 is a graph showing a change in a stress of a tungsten film when an argon gas flow rate is caused to change.

FIG. 5 is a graph showing a change in a stress of a tungsten film when a bias electric power is caused to change.

FIG. 6 is a graph showing a change in a stress of a tungsten film when the time until impedance matching at the time of supplying the bias electric power is caused to change.

### DESCRIPTION OF EMBODIMENTS

Now, referring to figures, an embodiment of a hard mask Hm and a method of producing a hard mask of the invention which, when dry etching treatment is performed with respect to a substrate to be treated (hereinafter referred to as “substrate Sw”), a dry etching treatment range is limited by being formed at a surface of the substrate Sw, is described.

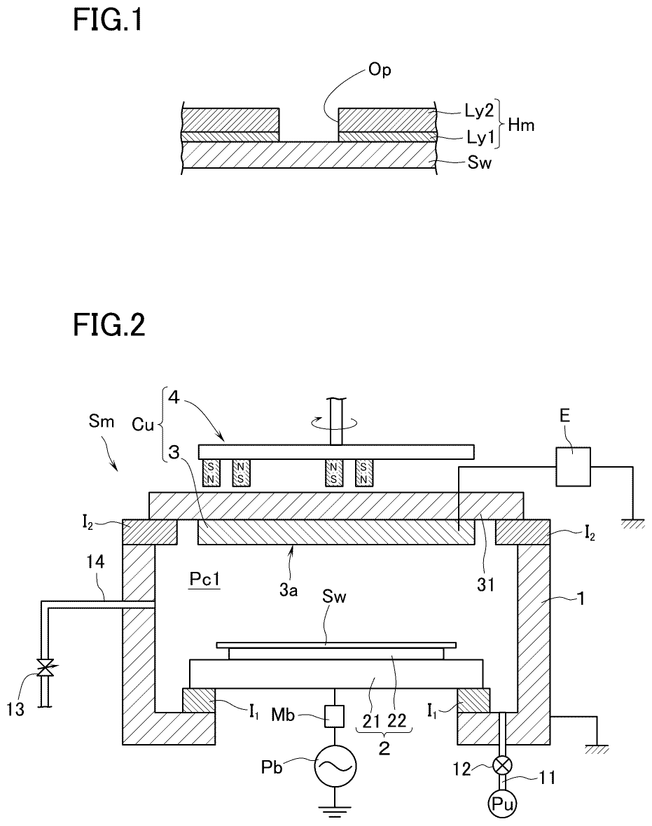

Referring to FIG. 1, a hard mask Hm has a tungsten nitride (WN) film Ly1 deposited on the surface of the substrate Sw and a tungsten (W) film Ly2 laminated on the tungsten nitride film Ly1. As a substrate Sw, a substrate such as a silicon wafer or the like and a composite of a predetermined thin film (for example, (an insulating film such as a SiO₂ film (a TEOS film) or the like and a metallic film such as an Al film or the like) deposited on the surface of the substrate Sw may be used. A film thickness of the tungsten nitride film Ly1 can be set within a range of, for example, 5 to 15 nm. A film thickness of the tungsten film Ly2 can be set within a range of, for example, 100 to 500 nm, for example. Further, at the hard mask Hm, an opening part Op having a predetermined contour is patterned and formed by known lithography technology, and a portion of the substrate Sw exposed in a bottom part of the opening part Op is dry-etched so that the hard mask Hm is formed into a desired etched-shape. The method of producing the hard mask Hm will be described below.

Referring to FIG. 2, Sm is a sputtering apparatus Sm capable of carrying out the method of producing the hard mask Hm of the embodiment. The sputtering apparatus Sm includes a vacuum chamber 1 capable of forming a vacuum atmosphere, and a processing chamber Pc is divided by the vacuum chamber 1. An exhaust pipe 11 communicating with a vacuum pump unit Pu composed of a turbo molecular pump and a rotary pump or the like is connected to a bottom wall of the vacuum chamber 1 so that the vacuum chamber 1 can be evacuated to a vacuum. A conductance valve 12 is interposed into the exhaust pipe 11 to adjust an effective exhaust velocity of the vacuum pump unit Pu. A gas pipe 14 into which a mass flow controller 13 is interposed is connected to a side wall of the vacuum chamber 1 so that a rare gas (for example, argon gas) and nitrogen gas can be introduced into the vacuum chamber 1 of the vacuum atmosphere at a predetermined flow rate, respectively. In the following, terms representing a direction, such as “up” and “down” or the like, will be described using an installed posture shown in FIG. 2.

A stage 2 is disposed on a bottom part of the vacuum chamber 1. The stage 2 includes a base 21 and a chuck plate 22 mounted on the base 21. The base 21 is made of a metal (for example, SUS) having thermal conductivity, which is mounted at a lower wall of the vacuum chamber 1 through an insulator I₁. An output from a high-frequency power source as a bias power source Pb is connected to the base 21 through a matching box Mb, and a predetermined bias electric power can be supplied to the substrate Sw by supplying a high-frequency electric power of a predetermined frequency (for example, 13.56 MHz) to the base 21. It should be noted that since known articles are used as the chuck plate 22, the bias power source Pb and the matching box Mb, respectively, a more detailed description of them is omitted. In addition, although not described with a specific illustration, a heater and a refrigerant curation path are assembled in the base 21. Electricity is supplied to the heater from an external power source, or a refrigerant is circulated in the refrigerant circulation path from a chiller unit, not shown, and the substrate Sw can be controlled to a predetermined temperature due to thermal conductivity from the base 21.

A cathode unit Cu is attached to a ceiling part of the vacuum chamber 1. The cathode unit Cu has a target 3 disposed opposite to the substrate Sw and made of tungsten, and a magnet unit 4 disposed above the target 3. The target 3 has a shape (circle in a plan view) depending on a contour of the substrate Sw, and is attached to a lower surface of a backing plate 31 that is mounted in the vacuum chamber 1 through an insulator I₂. An output from a sputtering power source E, such as a DC power source or the like, is connected to the target 3, and a predetermined electric power can be supplied to the target 3 at the time of deposition. Since a known article having a structure in which a magnetic field is generated in a lower space below a sputtering surface 3a of the target 3, electrons or the like ionized below the sputtering surface 3a of the target 3 are captured during sputtering, and sputtered particles scattered from the target 3 are efficiently ionized can be applied to the magnet unit 4, a detailed description of the magnet unit 4 is omitted here.

In addition, the sputtering apparatus Sm, which is not shown in the figure, has a known control device including a microcomputer, a sequencer, or the like. The control device can collectively control an operation of the sputtering power source E and the bias power source Pb, an opening degree of the conductance valve 12, an operation of the mass flow controller 13, the vacuum pump unit Pu, the magnet unit 4, or the like. In the following, the method of producing the hard mask Hm using the above sputtering apparatus Sm will be described specifically.

The substrate Sw is mounted on an upper surface of the stage 2 disposed in the vacuum chamber 1, when a predetermined pressure in the vacuum chamber 1 is reached by evacuating to the vacuum, the argon gas and the nitrogen gas are introduced into the vacuum chamber 1 at flow rates of 150 to 300 sccm and 100 sccm or more, respectively (at this time, a flow rate ratio of the argon gas to the nitrogen gas and a pressure in the vacuum chamber 1 are set to 1.5 or less and 1 Pa or more, respectively), and a DC electric power having a negative potential (for example, 2 kW to 6 kW) is supplied to the target 3 from the sputtering power source E. This causes a plasma atmosphere to be formed in the vacuum chamber 1, the target 3 made of tungsten to be reactive-sputtered, and the tungsten nitride film Ly1 to be deposited on the surface of the substrate Sw (a first step). It should be noted that when each of the flow rates of the argon gas and the nitrogen gas is introduced by setting so that the flow rate ratio of the argon gas to the nitrogen gas becomes 1.5 or less and but the pressure in the vacuum chamber 1 does not reach 1 Pa, all to do is that the pressure in the vacuum chamber 1 is maintained at 1 Pa or more by adjusting the effective exhaust velocity of the vacuum pump unit Pu by the opening degree of the conductance valve 12. However, when the pressure in the vacuum chamber 1 becomes, for example, 30 Pa or more, stress adjustment of the tungsten film Ly2 in the subsequent second step becomes difficult. In the first step, the bias electric power (for example, 50 W to 300 W) may be supplied to the substrate Sw from the bias power source Pb during deposition.

When the tungsten nitride film Ly1 is deposited on the surface of the substrate Sw in a predetermined film thickness (after the first step), only the introduction of the nitrogen gas is stopped and, in a state in which only the argon gas is introduced at a flow rate of 150 to 300 sccm (at this time, the pressure in the vacuum chamber 1 becomes 0.1 Pa to 30 Pa) into the vacuum chamber 1, the electric power supplied from the sputtering power source E to the target 3 is changed within, for example, 4 kW to 12 kW. This causes the target 3 made of tungsten to be sputtered and the tungsten film Ly2 to be deposited (laminated) on a surface of the tungsten nitride film Ly1 in a predetermined film thickness (the second step). In the second step, as similar to the first step, the bias electric power (for example, 50 W to 300 W) may be supplied from the bias power source Pb to the substrate Sw. Further, after deposition of the tungsten film Ly2, an opening part Op is patterned and formed at the tungsten film Ly2 and the tungsten nitride film Ly1 using the known lithography technology or the like. It should be noted that when the pressure in the vacuum chamber 1 exceeds 30 Pa, stress the adjustment of the tungsten film Ly2 becomes difficult in the second step.

According to the above, a microcrystalline tungsten film Ly2 of which a grain size is small (for example, 60 nm or less) can be deposited over an entire in-plane direction of the substrate Sw by setting the flow rate ratio of the rare gas to the nitrogen gas and the pressure in the vacuum chamber 1 to 1.5 or less and 1 Pa or more, respectively, in the first step, and depositing the tungsten film Ly2 on the surface of the tungsten nitride film Ly1 in the subsequent second step.

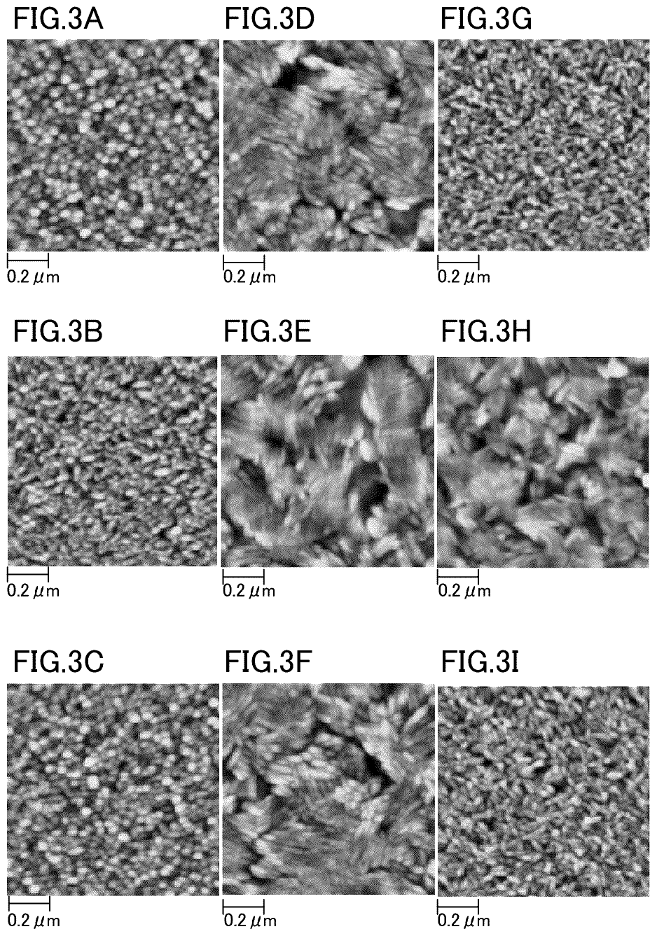

To confirm the above effect, the following experiments were carried out using the above sputtering apparatus Sm. In Invention Experiment, an article obtained by depositing the SiO₂ (TEOS) film od 100 nm on the surface of the silicon wafer of 300 nm was made the substrate Sw, the argon gas at the flow rate of 300 sccm and the nitrogen gas at the flow rate of 200 sccm (the flow rate ratio of the argon gas to the nitrogen gas was 1.5) were introduced into the vacuum chamber 1, respectively, and the pressure in the vacuum chamber 1 was maintain at 1 Pa by adjusting the opening degree of the conductance valve 12. The DC electric power of 3 kW was supplied to the target 3 made of tungsten and the bias electric power of 300 W was supplied to the substrate Sw. Then, the tungsten nitride film Ly1 of 5 nm was deposited (the first step). Thereafter, the argon gas at the flow rate of 150 sccm was introduced into the vacuum chamber 1, and the DC electric power of 6 kW was supplied to the target 3 made of tungsten. Then, the tungsten film Ly2 of 195 nm was deposited (second step). The surface of the tungsten film Ly2 at a central part (FIG. 3A), a peripheral edge part (FIG. 3B) and an intermediate part therebetween (FIG. 3C) of the substrate Sw on which the tungsten film Ly2 was deposited was observed by an atomic force microscope (AFM). The results are shown in FIGS. 3A to 3C. According to these, compared to the results of Comparative Experiment No. 1 (FIGS. 3D to 3F) and Comparative Experiment No. 2 (FIGS. 3G to 3I) described below, it was confirmed that the tungsten film Ly2 is configured by the microcrystal of which the grain size is small over the entire in-plane direction of the substrate Sw. In addition, after observing the surface of the tungsten film Ly2 by a scanning transmission electron microscope, the grain size is 60 nm or less.

As Comparative Experiment No. 1 with respect to Invention Experiment, the substrate Sw on which the tungsten film Ly2 was deposited was obtained by a method similar to that of Invention Experiment except that the flow rates of the argon gas and the nitrogen gas which were introduced into the vacuum chamber 1 were made 150 sccm and 70 sccm, respectively (the flow rate ratio of the argon gas to the nitrogen gas was 2.1), and the pressure in the vacuum chamber 1 was maintained at less than 1 Pa in the first step. Similar to Invention Experiment, the surface of the tungsten film Ly2 at a central part (FIG. 3D), a peripheral edge part (FIG. 3E) and an intermediate part therebetween (FIG. 3F) of the substrate Sw on which the tungsten film Ly2 was deposited was observed by the atomic force microscope (AFM). As a result, it was confirmed that the tungsten film Ly2 is a crystalline film of which a grain size is large over an entire in-plane direction of the substrate Sw, compared to that of Invention Experiment. In addition, the grain size is 100 nm or more by observing the surface of the tungsten film Ly2 by STEM.

In Comparative Experiment No. 2, the substrate Sw on which the tungsten film Ly2 was deposited was obtained by a method similar to that of Invention Experiment except that the flow rates of the argon gas and the nitrogen gas which were introduced into the vacuum chamber 1 were made 132 sccm and 88 sccm, respectively (the flow rate ratio of the argon gas to the nitrogen gas was 1.5) in the first step, and the pressure in the vacuum chamber 1 was maintained at less than 1 Pa. Similar to Invention Experiment, the surface of the tungsten film Ly2 at a central part (FIG. 3G), a peripheral edge part (FIG. 3H) and an intermediate part therebetween (FIG. 3I) of the substrate Sw on which the tungsten film Ly2 was deposited was observed by the atomic force microscope (AFM). As a result, it was confirmed that while the central part and the intermediate part are a microcrystal of which the grain size is small, the peripheral part is the crystalline film of which the gran size was large.

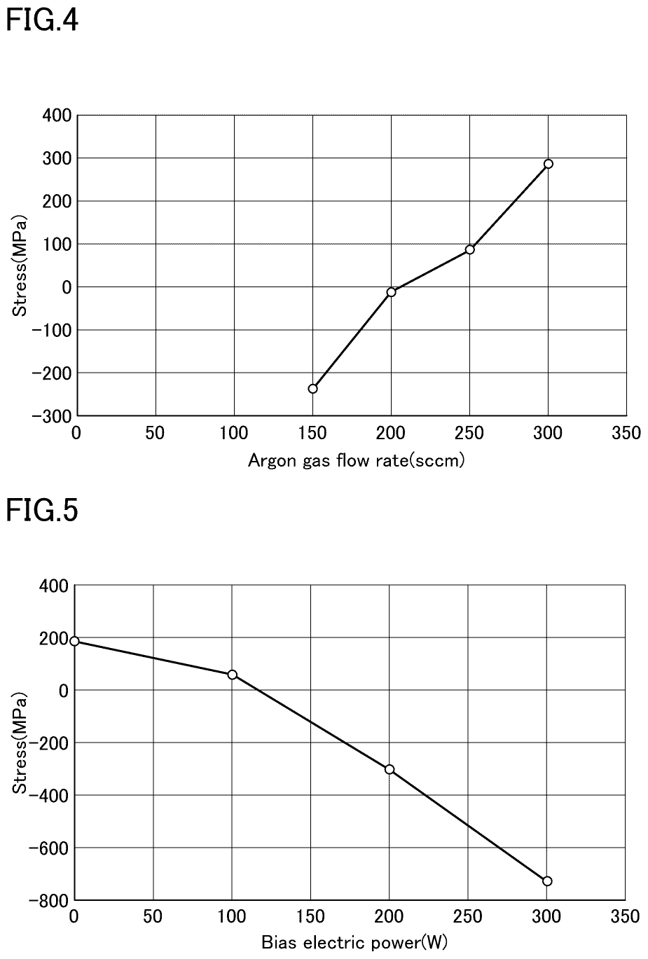

Next, an experiment of depositing the tungsten film Ly2 on the tungsten nitride film Ly1 was carried out using the substrate Sw on which the tungsten nitride film Ly1 was deposited under a condition of the first step of Invention Experiment (i.e., the flow rate ratio of the argon gas to the nitrogen gas and the pressure in the vacuum chamber 1 were 1.5 and 1 Pa, respectively). In this case, the electric power (DC electric power) supplied to the target 3 made of tungsten was set to 6 kW. Further, in the second step, the flow rate of the argon gas introduced into the vacuum chamber 1 was changed within a range of 150 to 300 sccm, and the tungsten film Ly2 of 195 nm was deposited (at this time, the pressure in the vacuum chamber 1 becomes within a range of 0.1 Pa to 30 Pa). A stress (MPa) of the tungsten film Ly2 deposited while changing the flow rate of the argon gas was measured by a thin film stress measuring apparatus, and the obtained result is as shown in FIG. 4. According to this, it was confirmed that when the pressure (total pressure) in the vacuum chamber 1 is increased in the second step, the stress of the tungsten film Ly2 changes from a compression direction to a tensile direction through a zero point and further increases in the tensile direction. In addition, it was confirmed that the tungsten film Ly2 deposited by changing the flow rate of the argon gas is also the microcrystalline film of which the grain size is small over the entire in-plane direction of the substrate Sw.

In addition, the substrate Sw on which the tungsten nitride film Ly1 under the conditions of the first step of Invention Example was used, and the electric power (DC electric power) supplied to the target 3 made of tungsten and the flow rate of the argon introduced into the vacuum chamber 1 were set to 6 kW and 300 sccm, respectively, in the second step. Further, while the bias electric power supplied from the bias power source Pb to the substrate Sw was changed within a range of 0 to 300 W, the tungsten film Ly2 of 195 nm was deposited. The stress (MPa) of the tungsten film Ly2 deposited by changing the bias electric power was measured by the thin film stress measuring apparatus, and the obtained result is shown in FIG. 5. According to this, it was confirmed that when the supplied bias electric power is increased, the stress of the tungsten film Ly2 changes from a tensile direction to a compression direction through a zero point and further increases in the compression direction. In addition, it was confirmed that the tungsten film Ly2 deposited by changing the bias electric power is also the microcrystalline film of which the grain size is small over the entire in-plane direction of the substrate Sw.

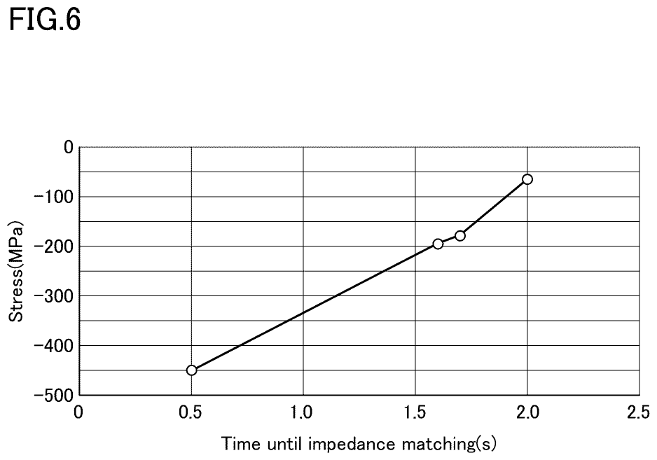

Further, the substrate Sw on which the tungsten nitride film Ly1 was deposited under the conditions of the first step of Experiment Invention was used, and in the second step, the electric power (DC electric power) supplied to the target 3 made of tungsten, the flow rate of the argon gas introduced into the vacuum chamber 1, the pressure in the vacuum chamber 1, and the bias electric power supplied from the bias power source Pb to the substrate Sw were set to 6 kW, 150 sccm, 10 Pa or more, and 800 W, respectively. Furthermore, the tungsten film Ly2 of 195 nm was deposited by changing the time until the impedance matching by the matching box Mb within a range of 0.5 to 2.0 s. The stress (MPa) of the tungsten film Ly2 deposited by changing the time until the impedance matching was measured by the thin film stress measuring apparatus. The obtained result is shown in FIG. 6. According to this, as the time until the impedance matching is extended, it was confirmed that the stress of the tungsten film Ly2 decreases in the compression direction. In addition, it was confirmed that the tungsten film Ly2 deposited by changing the time until the impedance matching is also the microcrystalline film of which the grain size is small over the entire in-plane direction of the substrate Sw.

Based on the above knowledge, the stress of the tungsten film Ly2 can be adjusted within a predetermined range (for example, within ±300 MPa, more preferably, for example, within 100 MPa) depending on the film thickness thereof by controlling at least one of the total pressure in the vacuum chamber 1 and the bias electric power supplied to the substrate Sw at the time of deposition in the second step. In addition, in the case where the bias electric power to the substrate Sw is supplied by the bias power source Pb connected through the matching box Mb by controlling the time until the impedance matching by the matching box Mb, even though the pressure in the vacuum chamber 1 is relatively high (for example, 10 Pa) in the second step, the stress of the tungsten film Ly2 can be adjusted within the predetermined range depending on the film thickness thereof.

Although the embodiment of the invention is described, various modifications are possible as long as they do not depart from the scope of the technical conception. In the embodiment, the case in which the total pressure in the vacuum chamber 1, the bias electric power supplied to the substrate Sw during deposition, and the time until the impedance matching are independently changed, and the stress of the tungsten film Ly2 is adjusted is describes as an example. However, conditions of two or more of them are simultaneously changed and the stress of the tungsten film Ly2 can be adjusted.

Explanation of symbols

| Mb | Matching box |
|---|---|
| Ly1 | Tungsten nitride film |
| Ly2 | Tungsten film |
| Pb | bias power source (AC power source) |
| Pc | Processing camber |
| Sw | Substrate (Substrate to be treated) |
| 3 | Target |

1. (canceled)

2. (canceled)

3. A method of producing a hard mask, comprising:
a first step in which a target is made of tungsten, a rare gas and nitrogen gas are introduced into a processing chamber of a vacuum atmosphere, and a tungsten nitride film is deposited on a surface of a substrate to be treated by a reactive sputtering manner; and
a second step in which a target is made of tungsten, and a tungsten film is deposited on a surface of the tungsten nitride film in a processing chamber of the vacuum atmosphere,
wherein a flow rate ratio of the rare gas to the nitrogen gas and a pressure in the processing chamber are set to 1.5 or less and 1 Pa or more, respectively, in the first step, a stress is adjusted depending on a film thickness of the tungsten film by controlling at least one of a total pressure in the processing chamber and a bias electric power supplied to the substrate to be treated at the time of deposition in the second step, and whereby a microcrystalline tungsten film of which a grain size is 60 nm or less is deposited over an entire in-plane direction of the substrate to be treated.

4. The method of producing a hard mask as claimed in claim 1, wherein, in the second step, the argon gas is introduced so that a total pressure inside the treatment room becomes within a range of 0.1 Pa to 30 Pa.

5. The method of producing a hard mask as claimed in claim 1 or 2, wherein, in the second step, the bias electric power is supplied to the substrate to be treated within a range of 0 W to 300 W.

6. The method of producing a hard mask as claimed in claim 1 or 2, wherein the stress is adjusted within ±300 MPa depending on the film thickness of the tungsten film.

7. The method of producing a hard mask as claimed in claim 1, wherein the bias electric power to the substrate to be treated is supplied by an AC power source connected through a matching box, and
wherein control of the bias electric power includes the time until an impedance matching by the matching box.
